(19) United States
(12) Patent Application Publication
(10) Pub. No.: US 2026/0324444 A1
(43) Pub. Date: Oct. 15, 2026

(54) SEMICONDUCTOR DEVICE AND METHOD OF MANUFACTURING THE SAME

(71) Applicant: Taiwan Semiconductor Manufacturing Co., Ltd., Hsinchu (TW)

(72) Inventors: Chin-Ying TSAI, Hsinchu (TW); Tsung-Yang HSIEH, Hsinchu (TW); Zhi-Wei ZHUANG, Hsinchu (TW); Chien-Ying WU, Hsinchu (TW); Chia-Wen HSUEH, Hsinchu (TW)

(73) Assignee: Taiwan Semiconductor Manufacturing Co., Ltd., Hsinchu (TW)

(21) Appl. No.: 19/178,625

(22) Filed: Apr. 14, 2025

(51) Int. Cl. H01L 23/64; H01L 21/48; H01L 23/498

(52) U.S. Cl. CPC H10W 44/601; H10W 70/05; H10W 70/095; H10W 70/635; H10W 70/65; H10W 70/685

(57) ABSTRACT

An interposer die includes a first semiconductor layer, an insulator layer on the first semiconductor layer, and a second semiconductor layer on the insulator layer and separated from the first semiconductor layer by the insulator layer. The interposer die includes a first through-semiconductor via extending from a top surface of the second semiconductor layer, through the insulator layer, to a bottom surface of the first semiconductor layer.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per die area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

With this scaling down of integrated circuit features, various efforts have also been made to address issues associated with packaging of integrated circuits. In some cases, an integrated circuit package includes a substrate, one or more integrated circuit dies, and an interposer between the substrate and the integrated circuit dies. However, there are many difficulties associated with such packaging that can result in scrapped wafers or other drawbacks.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1G are cross-sectional views of an interposer die, in accordance with some embodiments.

FIG. 2 is a cross-sectional view of an interposer die, in accordance with some embodiments.

FIG. 3 is a cross-sectional view of an interposer die, in accordance with some embodiments.

FIGS. 4A-4E are cross-sectional of an interposer die at various stages of processing, in accordance with some embodiments.

FIGS. 5A-5C are cross-sectional of an interposer die at various stages of processing, in accordance with some embodiments.

FIGS. 6A-6B are cross-sectional of an interposer die at various stages of processing, in accordance with some embodiments.

FIG. 7 is an illustration of an integrated circuit package, in accordance with some embodiments.

FIG. 8 is a cross-sectional view of an integrated circuit die, in accordance with some embodiments.

FIG. 9 is a cross-sectional view of an integrated circuit die, in accordance with some embodiments.

FIG. 10 is a flow diagram of a method of forming an integrated circuit die, in accordance with some embodiments.

FIG. 11 is a flow diagram of a method of forming an integrated circuit die, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

Embodiments of the present disclosure provide an interposer die including an embedded deep trench capacitor (DTC) and having backside contacts with improved electrical characteristics. Embodiments of the present disclosure utilize an insulator layer between two semiconductor layers in the interposer die. The interposer die also includes one or more through-semiconductor vias extending through the second semiconductor layer, the insulator layer, and the first semiconductor layer to a backside of the first semiconductor layer. Backside contacts are coupled to the through-semiconductor vias. The presence of the insulator layer will help reduce the presence of unwanted copper residue at the backside of the first semiconductor layer during charging of the deep trench capacitor. The result is that backside contacts can be formed with a better semiconductor surface profile. The results in reduced leakage. This also results in fewer scrapped wafers. When the interposer die is embedded in an integrated circuit package, the overall integrated circuit package will have much higher performance. Embodiments of the present disclosure also result in fewer scrapped integrated circuit packages.

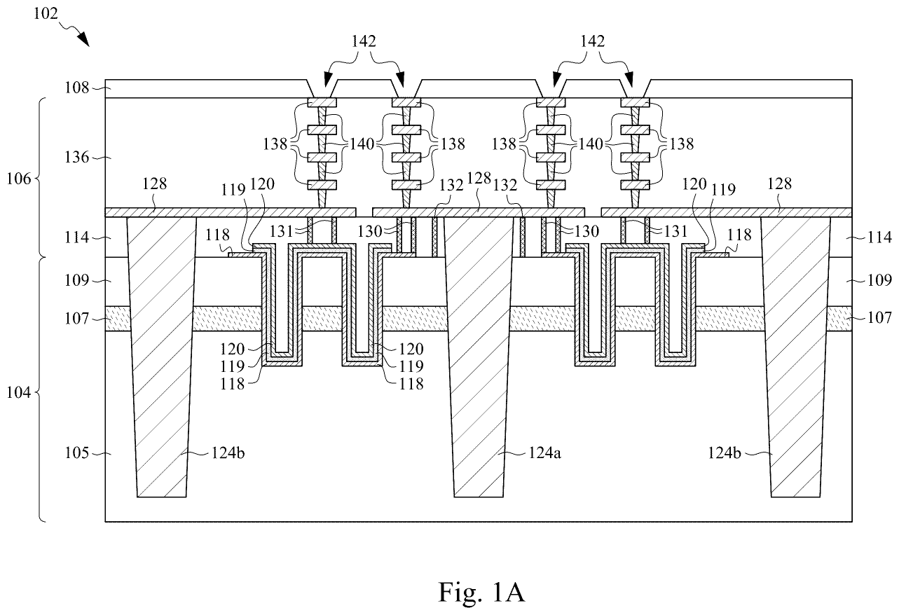

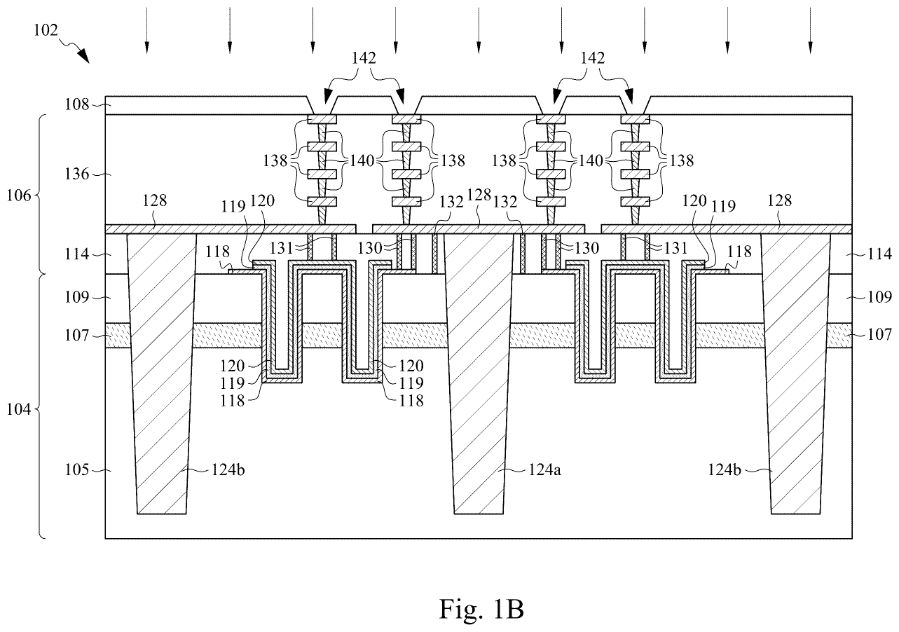

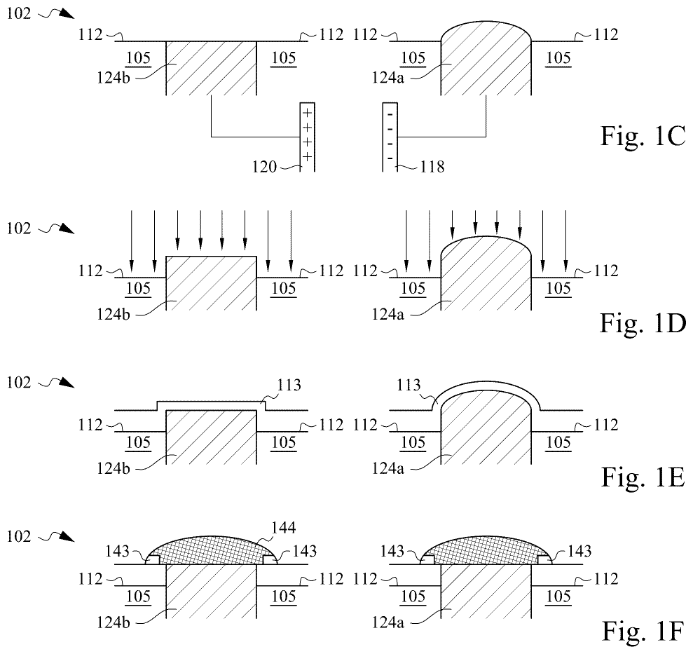

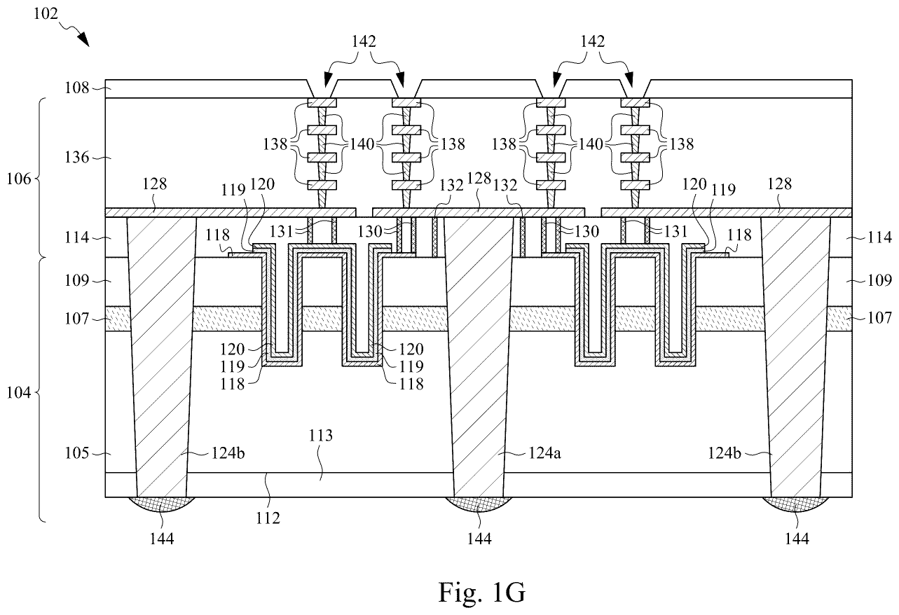

FIGS. 1A-1G are cross-sectional views of an interposer die at intermediate stages of processing, in accordance with some embodiments. In some embodiments, the interposer die 102 is an integrated circuit die that will be implemented in an integrated circuit package as one of a plurality of other integrated circuit dies in the package. As will be set forth in more detail below, the structure of the interposer die 102 helps to reduce leakage currents associated with bottom contact structures. The interposer die 102 may also be termed “an interposer”.

The integrated circuit die 102 includes a semiconductor region 104. The semiconductor region 104 includes a first semiconductor layer 105, and insulator layer 107 on the first semiconductor layer 105, and a second semiconductor layer 109 on the insulator layer 107. Accordingly, the semiconductor layer 109 is separated from the semiconductor layer 105 by the insulator layer 107. As will be set forth in more detail below, the presence of the insulator layer 107 between the semiconductor layer 105 and the semiconductor layer 109 helps to reduce leakage currents and helps to ensure proper formation of bottom contact structures.

In some embodiments, the semiconductor layer 105 is a bulk semiconductor layer. The semiconductor layer 105 is a monocrystalline semiconductor layer. In some embodiments, the semiconductor layer 105 includes silicon, silicon germanium, gallium arsenide, silicon carbide, or other semiconductor materials. In one particular example, the semiconductor layer 105 is intrinsic silicon. The semiconductor layer 105 has a thickness between 50 μm and 100 μm. The semiconductor layer 105 can have other materials and thicknesses without departing from the scope of the present disclosure.

In some embodiments, the insulator layer 107 is a layer of dielectric material. In some embodiments, the dielectric material of the insulator layer 107 includes one or more of SiO, SiN, SiC, SiON, SiCN, SiOCN, or other suitable dielectric materials. In some embodiments, the insulator layer 107 has a thickness between 200 nm and 2 μm. Other materials and thicknesses can be utilized for the dielectric layer 107 without departing from the scope of the present disclosure.

In some embodiments, the semiconductor layer 109 is a monocrystalline semiconductor layer. In some embodiments, the semiconductor layer 109 includes silicon, silicon germanium, gallium arsenide, silicon carbide, or other semiconductor materials. In one particular example, the semiconductor layer 105 is intrinsic silicon. The semiconductor layer 109 has a thickness between 70 nm and 7 μm. In some embodiments, the semiconductor layer 109 has a same material as the semiconductor layer 105. In a particular example, the semiconductor layer 105 and the semiconductor layer 109 are both silicon. The semiconductor layer 109 can have other materials and thicknesses without departing from the scope of the present disclosure.

In some embodiments, the semiconductor region 104 corresponds to a semiconductor on insulator (SOI) wafer. For example, the semiconductor region 104 can include a silicon on insulator wafer. In this example, the semiconductor layer 105 is a bulk semiconductor layer of the SOI wafer, the insulator layer is an oxide layer (or other dielectric material), and the semiconductor layer 109 corresponds to the active semiconductor layer of the SOI wafer.

In some embodiments, the semiconductor region 104 is not initially an SOI wafer. The insulator layer 107 is formed during processing of the interposer die 102. In particular, the semiconductor region 104 initially corresponds to simply to a bulk semiconductor layer 105. The insulator layer 107 is then formed on the bulk semiconductor layer 105.

In some embodiments, the insulator layer 107 is formed by deposition of the dielectric material. The deposition process can include chemical vapor deposition (CVD), an atomic layer deposition process (ALD), or another suitable deposition process. The insulator layer 107 has a material as described above.

In some embodiments, the insulator layer 107 is formed by an ion implantation process into the top surface of the bulk semiconductor layer 105. During the ion implantation process, the top surface of the semiconductor layer 105 is bombarded with ions having a selected energy. The ions are embedded within the bulk semiconductor layer at a depth range based on the image of the ions. The depth range is selected to correspond to the desired thickness of the insulator layer 107. As the ions are embedded in the upper portion of the bulk semiconductor layer 105, the composition of the bulk semiconductor layer 105 is changed from a semiconductor material to a dielectric material. In some embodiments, the semiconductor layer 105 include silicon and the ions include oxygen ions, resulting in an insulator layer 107 including SiO. In some embodiments, the semiconductor layer 105 include silicon and the ions include nitrogen ions, resulting in an insulator layer 107 including SiN. In some embodiments, the semiconductor layer 105 include silicon and the ions include carbon ions, resulting in an insulator layer 107 including SiC. Other types of ions in semiconductor materials can be utilized to form the insulator layer 107 without departing from the scope of the present disclosure.

In some embodiments, the insulator layer 107 is formed by a diffusion process into the top surface of the bulk semiconductor layer 105. During the diffusion process, the semiconductor layer 105 is heated to a temperature between 400 °C and 1000 °C. The gas including selected atoms, molecules, or compounds, is introduced into the environment of the semiconductor layer 105 during the time of elevated temperature. The atoms are diffused within the upper portion of bulk semiconductor layer. As the atoms are embedded in the upper portion of the bulk semiconductor layer 105, the composition of the bulk semiconductor layer 105 is changed from a semiconductor material to a dielectric material. In some embodiments, the semiconductor layer 105 include silicon and the atoms include oxygen ions, resulting in an insulator layer 107 including SiO. In some embodiments, the semiconductor layer 105 include silicon and the atoms include nitrogen ions, resulting in an insulator layer 107 including SiN. In some embodiments, the semiconductor layer 105 include silicon and the atoms include carbon ions, resulting in an insulator layer 107 including SiC. Other types of temperatures and materials can be utilized to form the insulator layer 107 without departing from the scope of the present disclosure.

After formation of the insulator layer 107 by ion implantation or diffusion, the semiconductor layer 109 is formed with an epitaxial growth process. In some embodiments, the insulator layer 107 retains enough of the crystalline structure of the bulk semiconductor layer 105 that an epitaxial growth process can result in a semiconductor layer 109 having a crystalline structure based on the crystalline structure of the semiconductor layer 105. Alternatively, the epitaxial growth process of the semiconductor layer 109 can be accomplished in other suitable matters.

In some embodiments, the interposer die 102 includes a plurality of the trench capacitors 116. The deep trench capacitors 116 each include a first electrode 118 and a second electrode 120. The first electrode 118 is a bottom electrode. The second electrode 120 is a top electrode. The first electrode 118 includes a layer of conductive material that lines the sidewalls and bottoms of trenches formed in the semiconductor layer 109, the insulator layer 107, and the semiconductor layer 105. In the example of FIG. 1A, each deep trench capacitor 116 includes two trenches. The conductive layer of the first electrode 118 is also positioned on a top surface 110 of the semiconductor layer 109. In some embodiments, the conductive layer includes W, Ti, Al, Au, Cu, Ta, Ru, Co, Mb, TiN, TaN, WN, AlN TiAl, or other suitable conductive materials.

In some embodiments, the trench deep capacitors 116 each include a dielectric layer 119 positioned between the first electrode 118 and the second electrode 120. The dielectric layer 119 includes one or more of HfO, SiO, SiN, SiOC, SiOCN, SiCN, or other suitable dielectric materials.

The second electrode 120 includes a layer of conductive material positioned on the dielectric layer 119. In some embodiments, the conductive layer of the second electrode 120 includes W, Ti, Al, Au, Cu, Ta, Ru, Co, Mb, TiN, TaN, WN, AlN TiAl, or other suitable conductive materials. In some embodiments, the second electrode 120 completely fills the trenches. In some embodiments, the second electrode 120 includes an additional metal layer that fills the remaining spaces in the trench. Alternatively, the remaining space in the trench can be filled by a subsequently deposited dielectric layer. Various other configurations can be utilized without departing from the scope of the present disclosure.

In some embodiments, the trenches of the deep trench capacitors 116 (and the first electrode 118 and the second electrode 120) extend from a top surface of the semiconductor layer 109, through the entire depth of the first semiconductor layer 109, through the entire depth of the insulator layer 107, and partially into the semiconductor layer 105. In some embodiments, the electrodes 118/120 of the deep trench capacitors 116 extends to a depth between 10 μm and 15 μm below the top surface of the semiconductor layer 109. Other depths can be utilized without departing from the scope of the present disclosure.

Though not apparent in the view of FIG. 1A, in some embodiments, the trenches of the deep trench capacitors 116 are each cylindrical such that a lateral cross-section in an X-Y plane (as opposed to the vertical direction Z) would show each electrode 118/120 as having a circular profile.

In some embodiments, the interposer die 102 includes a dielectric stack 106 on the semiconductor region 104. In particular, the dielectric stack 106 is formed above the semiconductor layer 109. The dielectric stack includes a dielectric layer 114 on a top surface of the semiconductor layer 109. The dielectric layer 114 can include one or more of SiO, SiN, SiC, SiON, SiOC, SiOCN, or other suitable dielectric materials.

The interposer die 102 includes a plurality of through-semiconductor vias 124. FIG. 1A illustrates a through-semiconductor via 124a and through-semiconductor vias 124b. As used herein, through-semiconductor vias 124 may omit the suffixes “a” and “b”, when description is generic to all of the through-semiconductor vias 124 or in other circumstances.

In an example in which the semiconductor layers 105 and 109 are silicon, the through-semiconductor vias 124 can be termed through silicon vias 124. At the stage of processing shown in FIG. 1A, the through-semiconductor vias 124 extend from a top surface of the insulator layer 114 through the entirety of the semiconductor layer 109, through the insulator layer 107, and through nearly an entirety of the semiconductor layer 105. As will be shown for the below, after further processing steps the through-semiconductor vias 124 will extend through an entirety of the semiconductor layer 105 such that bottom contacts can be coupled to the bottom surface 112 of the semiconductor layer 105 in through-semiconductor vias 124.

In some embodiments, the through-semiconductor vias 124 include a metal material. In the through-semiconductor vias 124 include one or more of W, Ti, Al, Au, Cu, Ta, Ru, Co, Mb, TiN, TaN, AlN TiAl, or other suitable conductive materials. The through-semiconductor vias 124 can also include one or more liner layers not shown in FIG. 1A. In a particular example described herein, the through-semiconductor vias 124 are Cu, though other materials can be utilized without departing from the scope of the present disclosure.

The interposer die 102 includes a plurality of metal tracks 128 formed on the dielectric layer 114 within the dielectric stack 116. The metal tracks 128 can include one or more of W, Ti, Al, Au, Cu, Ta, Ru, Co, Mb, TiN, TaN, AlN TiAl, or other suitable conductive materials. At least some of the metal tracks 128 are in direct contact with respective through-semiconductor vias 124.

The interposer die 102 includes a plurality of conductive vias 130, 131, and 132 formed in the dielectric layer 114. Each conductive via 130 extends between a metal track 128 and the bottom electrode 118 of a deep trench capacitor 116. Each conductive via 131 extends between a metal track 128 and the top electrode 120 of a deep trench capacitor. Each conductive via 132 extends between a metal track 128 and the semiconductor layer 109. The conductive vias 130, 131, and 132 can include one or more of W, Ti, Al, Au, Cu, Ta, Ru, Co, Mb, TiN, TaN, AlN TiAl, or other suitable conductive materials.

As can be seen in FIG. 1A, each through-semiconductor via 124b is electrically coupled to a top electrode 120 of a deep trench capacitor 116 via a metal track 128 and conductive vias 131. As can be seen in FIG. 1A, the through-semiconductor via 124a is electrically coupled to the bottom electrodes 118 of the deep trench capacitors 116 by a metal track 128 and conductive vias 130.

In some embodiments, the bottom electrodes 118 of the deep trench capacitors 116 are configured to be coupled to VSS (i.e., ground). In some embodiments, the top electrodes 120 of the deep trench capacitors 116 are configured to be coupled to VDD (i.e., a high supply voltage). Accordingly, during operation of the interposer die 102, the through-semiconductor via 124a is configured to carry VSS and the through-semiconductor vias 124b are configured to carry VDD, in accordance with some embodiments.

Though not shown in FIG. 1A, the interposer die 102 can include a plurality of through-semiconductor vias 124 that are not dedicated to carry other VDD or VSS. These other through-semiconductor vias 124 are configured to carry data signals from an integrated circuit die coupled above the interposer die 102 to a substrate or other integrated circuit die the interposer die 102 in integrated circuit package.

In some embodiments, the interposer die 102 includes a plurality of conductive vias 132. The conductive vias 132 are grounding vias each coupled between the central metal track 128 and the top surface of the semiconductor layer 109. Accordingly, the conductive vias 132 are configured to provide ground voltage to the top surface of the semiconductor layer 109. Though not shown in FIG. 1A, silicides or other structures may be formed on the top surface of the semiconductor layer 109 in contact with the conductive vias 132. The conductive vias 132 can include W, Ti, Al, Au, Cu, Ta, Ru, Co, Mb, TiN, TaN, AlN TiAl, or other suitable conductive materials.

The dielectric stack 106 includes a dielectric layer 136. Although the dielectric layer 136 is shown as a single dielectric layer in FIG. 1A, in practice, the dielectric layer 136 includes a plurality of dielectric layers. The plurality of dielectric layers can each include one or more of SiO, SiN, SiC, SiON, SiOC, SiOCN, or other suitable dielectric materials.

The interposer die 102 includes a plurality of metal tracks 138 formed in the dielectric layers 136, in accordance with some embodiments. Each level of metal tracks 138 can correspond to a metal layer (M1, M2, etc.) formed on a sub-layer of the dielectric layer 136. The metal tracks 138 can include W, Ti, Al, Au, Cu, Ta, Ru, Co, Mb, TiN, TaN, AlN TiAl, or other suitable conductive materials.

The interposer die 102 includes a plurality of conductive vias 140 formed in the dielectric layers 136, in accordance with some embodiments. The conductive vias 140 electrically couple metal tracks 138 of the different levels, or a metal track 138 and the lowest level to the metal track 128. The conductive vias can include W, Ti, Al, Au, Cu, Ta, Ru, Co, Mb, TiN, TaN, AlN TiAl, or other suitable conductive materials.

The interposer die 102 includes a passivation layer 108 on the dielectric stack 106, in accordance with some embodiments. The passivation layer 108 includes openings 142 exposing the top metal tracks 138. Though not shown in FIG. 1A, the top metal contacts can be formed on the top metal tracks 138 to facilitate electrically coupling the interposer die 102 to an integrated circuit die or other circuit device positioned on the interposer die 102 in integrated circuit package. In some embodiments, the top metal tracks 138 can correspond to top contact pads of the interposer die 102. In some embodiments, the top metal contacts can include solder bumps or solder balls positioned on the top metal tracks 138.

Though not shown in FIG. 1A, the dielectric stack 106 can include a plurality of other metal tracks 138 conductive vias 140, and metal tracks 128 configured to carry data signals to the through-semiconductor vias 124 that are configured to carry data signals. Accordingly, other openings 142 can be formed to expose the top metal tracks 138 to provide data signals to the interposer die 102, in accordance with some embodiments.

In FIG. 1B, the deep trench capacitors 116 have been charged, in accordance with some embodiments. In particular, the plates 118 of the deep trench capacitors 116 are charged to VSS or ground. The plates 120 of the deep trench capacitors 116 are charged to VDD or to another positive voltage. Accordingly, the through-semiconductor via 124a is charged to VSS while the semiconductor vias 124b are charged to ground. Furthermore, in some embodiments, one or more plasma-assisted processes such as a plasma enhanced deposition or etching process can result in charging.

As can be seen in FIG. 1B, negative charges have accumulated at the bottom of the semiconductor layer 109 at the top surface of the insular layer 107. Beneficial he, the negative charges are prevented by the insulator layer 107 from extending to the bottom surface 112 of the semiconductor layer 105. As will be shown in relation to subsequent figures, this prevention of charge accumulation at the bottom of the semiconductor layer 105 by the insulator layer 107 is highly beneficial to formation and function of the interposer die 102.

FIGS. 1C-1F are enlarged cross-sectional views of portions of the bottom surface of the semiconductor layer 105, in accordance with some embodiments. After the stage of processing shown in FIGS. 1A and 1B, the interposer die 102 is flipped for backside processing so that the bottom surface 112 of the semiconductor layer 105 is now facing upwards at the top of the figures.

In FIG. 1C, a CMP process has been performed, in accordance with some embodiments. The CMP process removes a portion of the semiconductor layer 112 to expose the ends of the through-semiconductor vias 124. However, as described previously, the electrodes 118 and 120 have been charged to VSS and VDD, respectively. During the CMP process, after exposure of the through-semiconductor via 124a, the negative charge of the through-semiconductor via 124a results in an extra accumulation of copper on the end of the through-semiconductor via 124a. This occurs because negatively charged portions of copper removed during the CMP process are drawn by electrostatic charge to the through-semiconductor via 124a.

In FIG. 1C, the exposed end of the through-semiconductor via 124b is substantially coplanar with the bottom surface 112 of the semiconductor layer 105. The different charge of the through-semiconductor vias 124b with respect to the through-semiconductor via 124a results in the lack of a voltage on the end of the through-semiconductor vias 124b.

FIG. 1C also illustrates a benefit of the presence of the insulator layer 107. In particular, there is not an accumulation of charge at the bottom surface 112 of the semiconductor layer 105. The lack of charge at the bottom surface 112 helps to ensure that there is no accumulation of copper on the bottom surface 112 of the semiconductor layer 105 adjacent to the exposed ends of the through-semiconductor vias 124b. In the absence of the insulator layer 107, it is possible that the bottom surface 112 of the semiconductor layer 105 would have an accumulation of negative charges during the CMP process, resulting in accumulations of copper material on the bottom surface 112 adjacent to the exposed ends of the. This undesired copper material could function as a hard mask during subsequent etching processes, resulting in degradation of bottom metal contacts and the deducing large leakage currents during operation of the interposer die 102.

In FIG. 1D, an etching process is performed to recess the top surface 112 of the semiconductor layer 105 with respect to the exposed ends of the through-semiconductor vias 124. The etching process selectively etches the semiconductor material of the semiconductor layer 105 with respect to the metal material of the through-semiconductor vias 124. The result is the recessing of the bottom surface 112 as shown in FIG. 1D.

If the insulator layer 107 was not present, the etching process shown in FIG. 1D may not properly recess the bottom surface 112 of the semiconductor layer 105 adjacent to the exposed ends of the through-semiconductor vias 124b. This can result in leakage currents and malformed bottom contacts described previously.

In FIG. 1E, a dielectric layer 113 has been deposited on the bottom surface 112 of the semiconductor layer 105 and on exposed portions of the through-semiconductor vias 124, in accordance with some embodiments. The dielectric layer 113 can include one or more of SiO, SiN, SiC, SiON, SiOC, SiOCN, or other suitable dielectric materials. The dielectric layer 113 can be formed by CVD, ALD, or other suitable deposition processes.

In FIG. 1F, a CMP process has been performed, in accordance with some embodiments. The CMP process removes portions of the dielectric layer 113 and the through-semiconductor vias 124 until the exposed surfaces of the dielectric layer 113 and the through-semiconductor vias 124 are substantially coplanar.

In FIG. 1F, mask structures 143 have been formed on the exposed surface of the dielectric layer 113, in accordance with some embodiments. The mask structures 143 can include a solder mask or other structures or materials.

In FIG. 1F, bottom contact structures 144 have been placed in contact with the exposed ends of the through-semiconductor vias 124, in accordance with some embodiments. The bottom contact structures 144 can include C4 solder bumps, or other types of contact structures that can facilitate electrical connection between the through-semiconductor vias 124 and conductive structures on a device or substrate on which the interposer 102 will be placed as part of an integrated circuit package.

In FIG. 1G, backside processing of the interposer die 102 is substantially complete, in accordance with some embodiments. In particular, the processes described in relation to FIGS. 1C-1E have been performed, resulting in the dielectric layer 113 on the bottom surface 112 of the semiconductor layer 105. The bottom contact structures 144 have been formed electrically coupled to the bottoms of the through-semiconductor vias 124. The interposer die 102 is now ready to be placed on a substrate as part of an integrated circuit package or other device package.

In some embodiments, a bottom dielectric stack is formed on the bottom of the semiconductor layer 105 during backend processing. In particular, rather than forming solder bumps in direct contact with exposed ends of the through-semiconductor vias 124, a stack of dielectric layers is formed including a plurality of metal tracks and conductive vias similar to those described in relation to the dielectric stack 106. Solder bumps or other bottom contact structures can then be placed on the bottom of the backside dielectric stack. The interposer die 102 can have other structures and compositions without departing from the scope of the present disclosure.

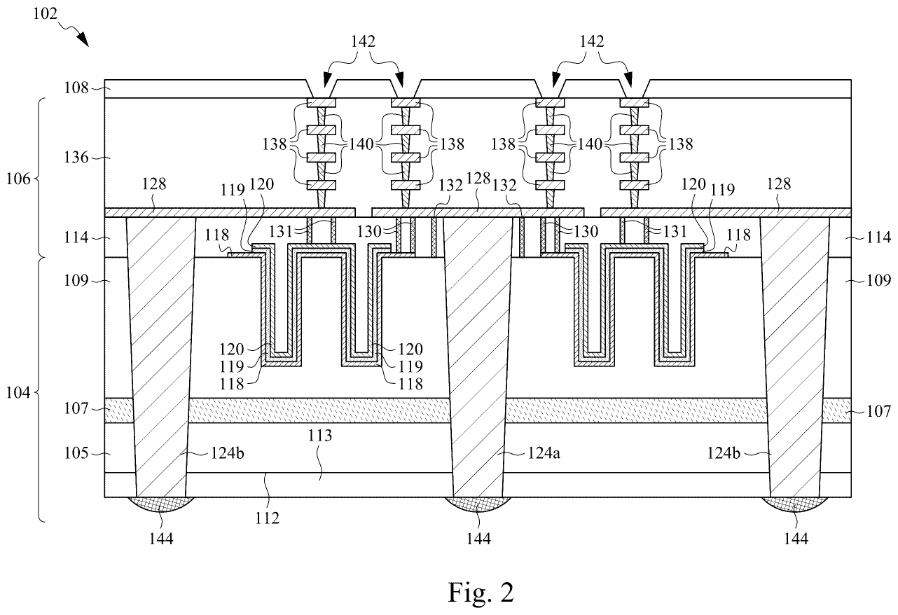

FIG. 2 is a cross-sectional view of an interposer die 102, in accordance with some embodiments. The interposer die 102 of FIG. 2 is substantially similar to the interposer die 102 of FIG. 1G. The interposer die 102 of FIG. 2 is different in that the insulator layer 107 is positioned below the bottoms of the electrodes 118/120 of the deep trench capacitors 116. The insulator layer 107 at this position still provides the benefit of preventing the accumulation of charge at the bottom surface 112 of the semiconductor layer 105 and the subsequent structural in leakage problems that can occur. Accordingly, the interposer die 102 of FIG. 2 retains the benefits of the insulator layer 107 described in relation to the interposer die 102 of FIGS. 1A-1G.

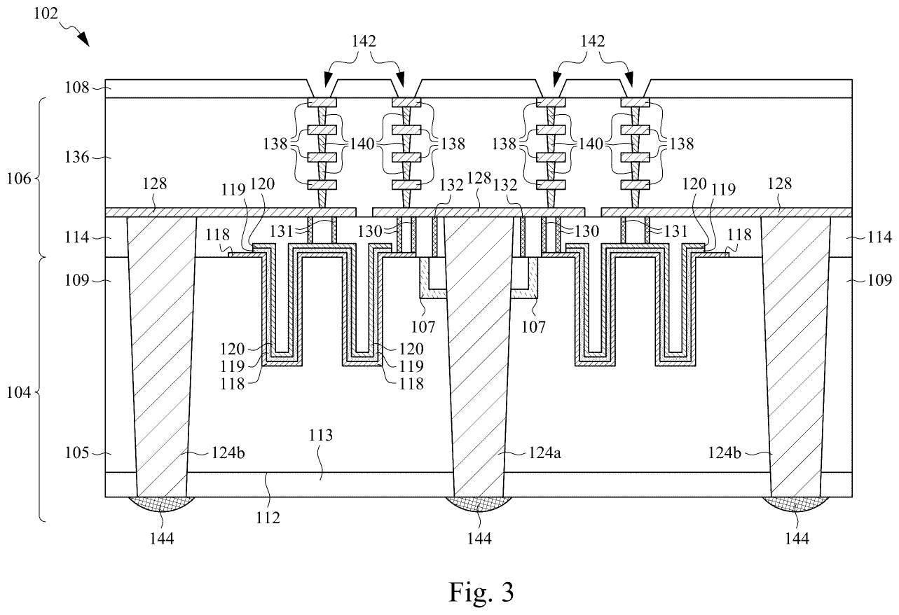

FIG. 3 is a cross-sectional view of an interposer die 102, in accordance with some embodiments. The interposer die 102 of FIG. 3 is substantially similar to the interposer die 102 of FIG. 1G. The interposer die 102 of FIG. 3 is different in that the insulator layer 107 is present only adjacent to the through-semiconductor via 124a. More particularly, vertical insulator columns 117 extend upward from the insulator layer 107 to the bottom surface of the dielectric layer 114, thereby forming an insulator structure 115 including the insulator layer 107 and the insulator columns 117. The insulator columns 117 can have a same material as the insulator layer 107.

In some embodiments, the insulator structure 115 laterally bounds the grounding vias 132. As described previously, the grounding vias 132 provide ground voltage to the top of the semiconductor layer 109. In the case of FIG. 3, the insulator columns 117 and the insulator layer 107 bound the portion of the semiconductor layer 105 that receives ground voltage from the grounding vias 132. In FIG. 3, the semiconductor material bounded by the insulator structure 115 corresponds to the semiconductor layer 109.

In some embodiments, the insulator layer 115 is formed in the following manner. Prior to formation of any conductive structures, the top of the semiconductor layer 105 is masked with a pattern only the central region at which the insulator structure 115 will be formed. An ion implantation process is then performed to form the insulator layer 107 at the exposed region at a selected depth. Subsequently, trenches are formed and filled with a dielectric material to form the insulator columns 117. Other processes can be utilized to form the insulator structure 115 without departing from the scope of the present disclosure.

The insulator structure 115 of FIG. 3 provides the benefits of preventing the accumulation of charge at the bottom surface 112 of the semiconductor layer 105 and the subsequent structural in leakage problems that can occur. Accordingly, the interposer die 102 of FIG. 3 retains the benefits of the insulator layer 107 described in relation to the interposer die 102 of FIGS. 1A-1G.

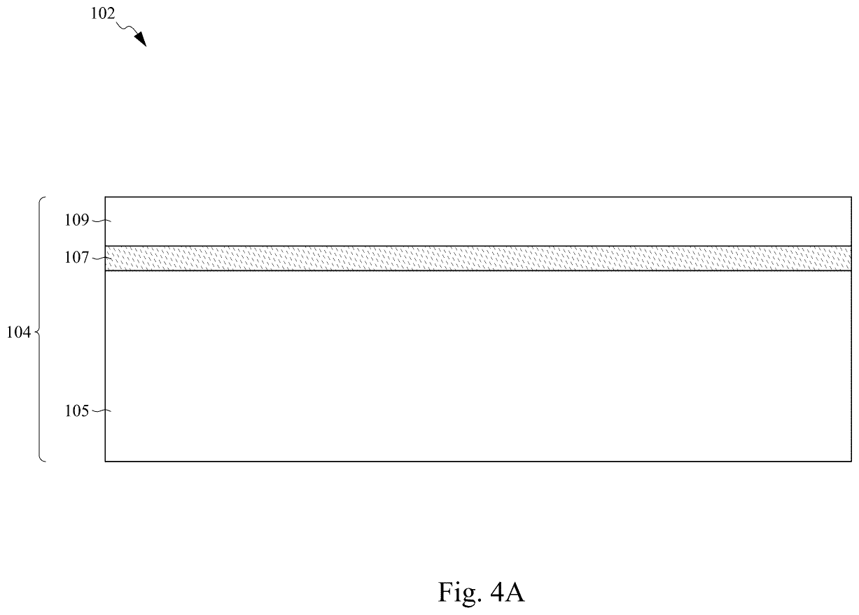

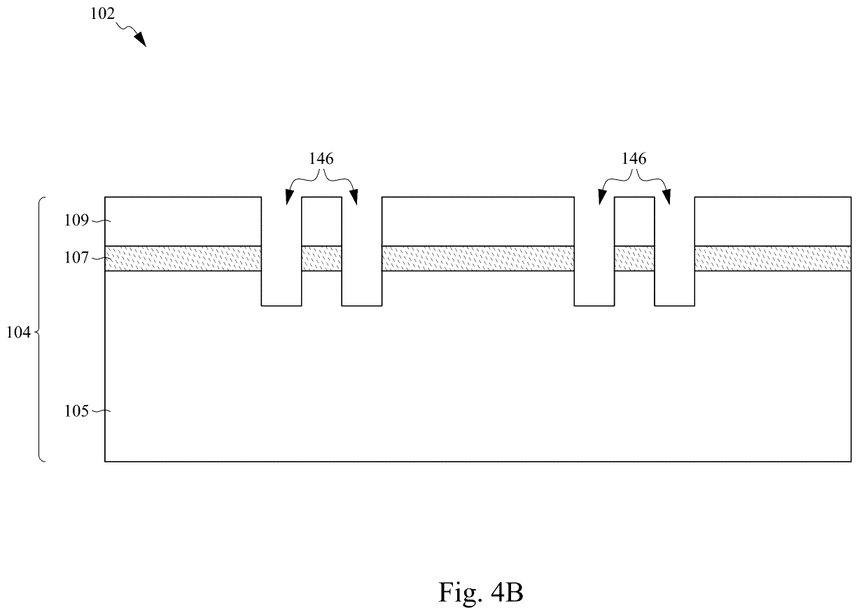

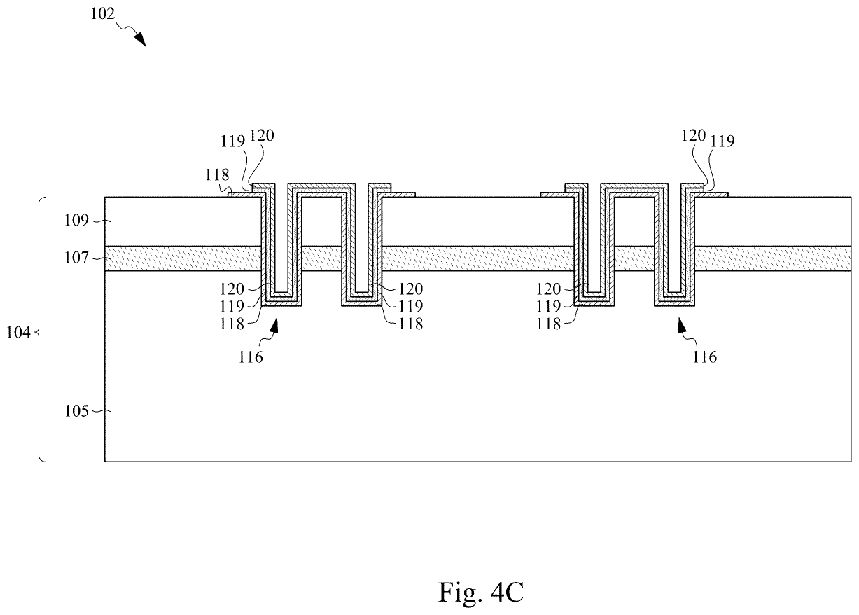

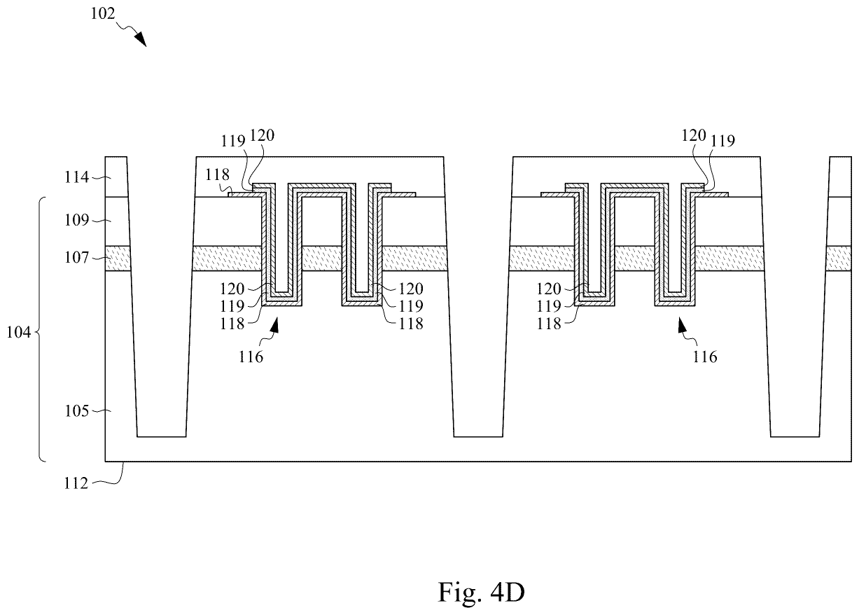

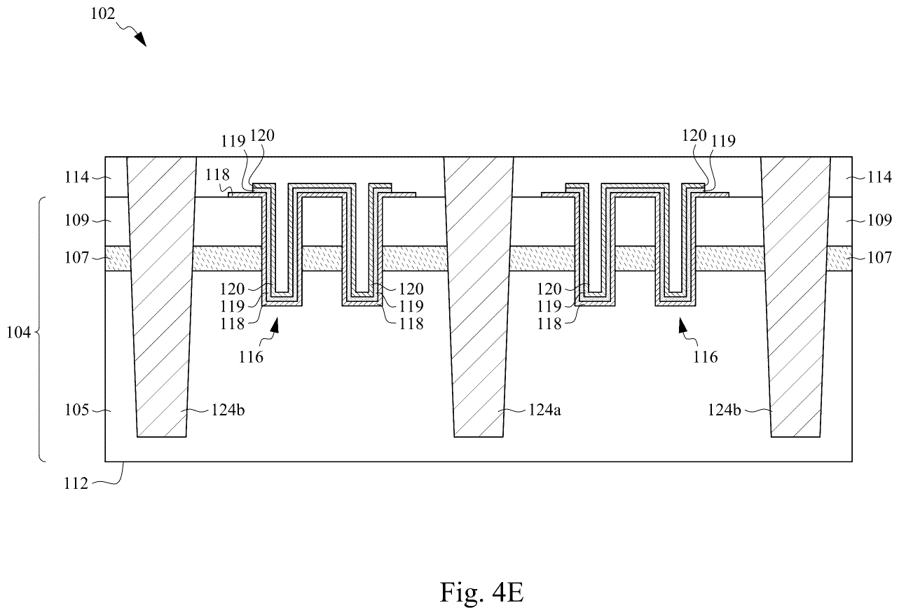

FIG. 4A-4E are cross-sectional views of an interposer die 102 at intermediate stages of processing, in accordance with some embodiments.

In FIG. 4A, the semiconductor region 104 corresponds to an SOI wafer, in accordance with some embodiments. The SOI wafer includes the semiconductor layer 105, the insulator layer 107, and the semiconductor layer 109 as described previously.

In FIG. 4B, trenches 146 have been formed through the semiconductor layer 109, the insulator layer 107, and partially into the semiconductor layer 105, in accordance with some embodiments. The trenches 146 can be formed by masking the semiconductor layer 109 with a pattern in accordance with the trenches 146. The trenches 146 can be formed to a selected depth by performing an anisotropic etching process that etches selectively in the downward direction.

In FIG. 4C, the electrodes 118/120 and the dielectric layer 119 of the deep trench capacitors 116 have been formed in the trenches 146, in accordance with some embodiments. The bottom electrode 118 can be formed by conformally depositing a first layer of conductive material in the trenches 146. The dielectric layer 119 can be formed by conformally depositing a dielectric material in the trenches on the bottom electrode 118. The top electrode 120 can be formed by conformally depositing the second layer of conductive material on the dielectric layer 119. The electrodes 118/120 can be formed by depositing a metal material in the trenches 146. Though not shown in FIG. 4C, a dielectric material can be formed lining the sides and bottoms of the trenches 146 prior to depositing the conductive material of the bottom electrode 118. The dielectric layer includes one or more of HfO, SiO, SiN, SiOC, SiOCN, SiCN, or other suitable dielectric materials.

In FIG. 4D, the dielectric layer 114 has been formed on the semiconductor layer 109, in accordance with some embodiments. The dielectric layer 114 has been formed on the top surface of the semiconductor layer 109. The dielectric layer 114 can have materials described previously can be formed by CVD, ALD, or other suitable deposition processes.

In FIG. 4D, trenches 148 have been formed through the dielectric layer 114, the semiconductor layer 109, the insulator layer 107, and nearly to the bottom of the semiconductor layer 105, in accordance with some embodiments. The trenches 148 can be formed by masking the top surface of the dielectric layer 114 with a pattern that exposes the dielectric layer 114 in accordance with placement of the trenches 148. An anisotropic etching process can then be performed to form the trenches 148. The trenches 148 do not extend to the bottom surface 112 of the semiconductor layer 105.

In FIG. 4E, the through-semiconductor vias 124 have been formed in the trenches 148, in accordance with some embodiments. The through-semiconductor vias 124 can be formed by depositing a conductive material in the trenches 148. The conductive material can include those described previously for the through-semiconductor vias 124. The through-semiconductor vias 124 will be exposed at the bottom surface 112 utilizing the processes described in relation to FIGS. 1C-1F. The other structures, including the through-semiconductor vias 124 of the interposer die 102 can be formed as described in relation to FIGS. 1A-4D.

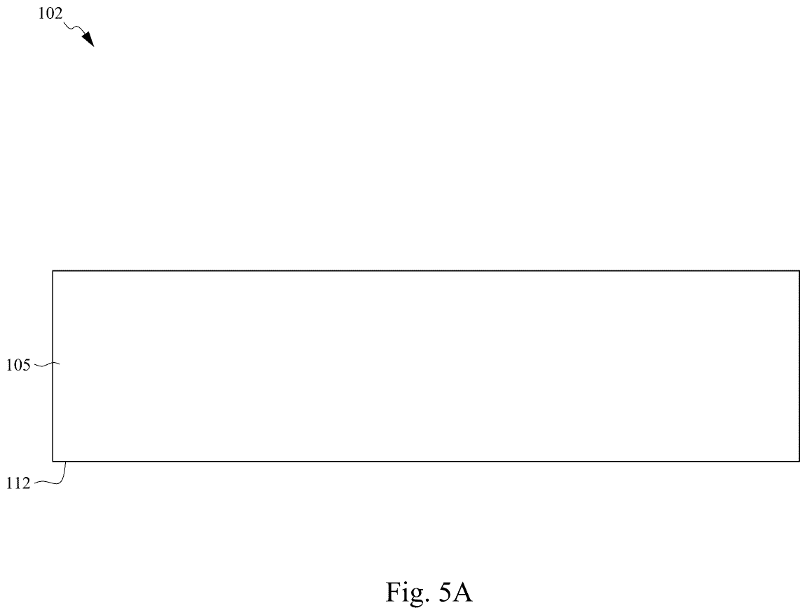

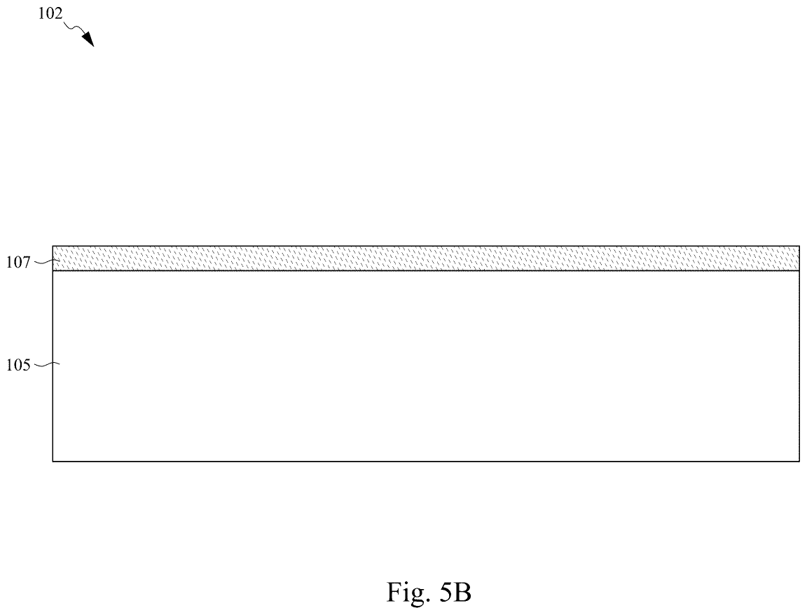

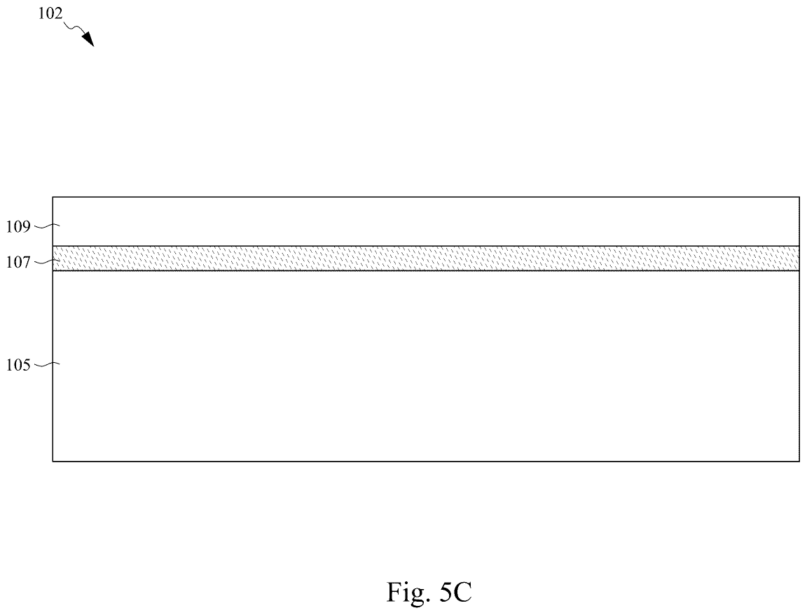

FIG. 5A-4C are cross-sectional views of an interposer die 102 at intermediate stages of processing, in accordance with some embodiments.

FIG. 5A illustrates the semiconductor layer 105 prior to formation of the insulator layer 107, in accordance with some embodiments. Accordingly, the semiconductor layer 105 corresponds to a semiconductor wafer at the stage of processing shown in FIG. 5A.

In FIG. 5B, the insulator layer 107 has been formed on the semiconductor layer 105, in accordance with some embodiments. The insulator layer 107 is formed by depositing a dielectric material on the semiconductor layer 105. The dielectric material can be deposited by CVD, ALD, or other suitable deposition processes and can have the materials described previously.

In FIG. 5C, the semiconductor layer 109 has been formed on the insulator layer 107, in accordance with some embodiments. The semiconductor layer 109 can be formed by performing an epitaxial growth process. Alternatively, the semiconductor layer 109 can be formed utilizing other deposition processes. The other structures, including the through-semiconductor vias 124 of the interposer die 102 can then be formed as described in relation to FIGS. 1A-4D.

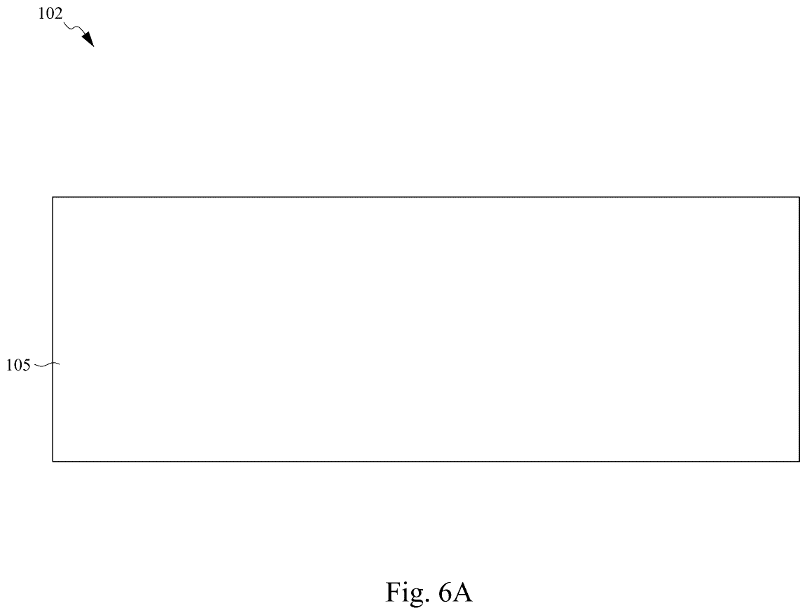

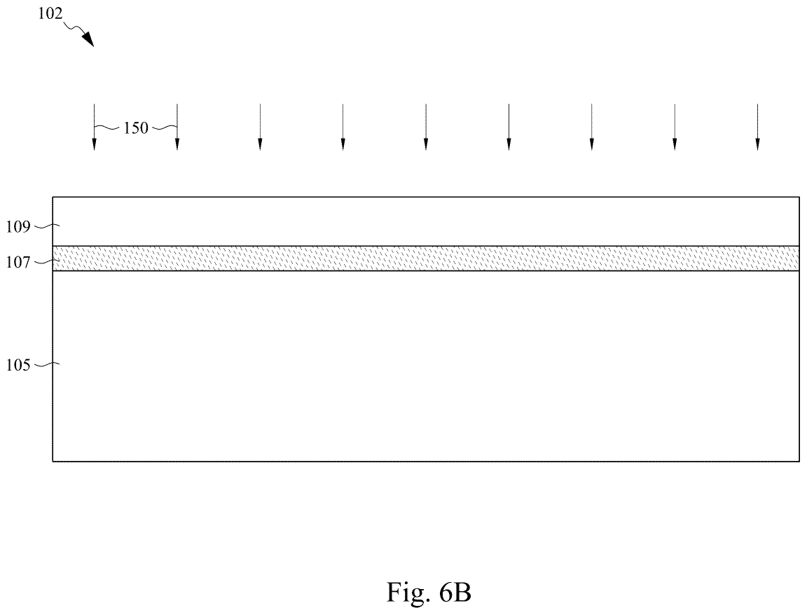

FIG. 6A-4C are cross-sectional views of an interposer die 102 at intermediate stages of processing, in accordance with some embodiments.

FIG. 6A illustrates the semiconductor layer 105 prior to formation of the insulator layer 107, in accordance with some embodiments. Accordingly, the semiconductor layer 105 corresponds to a semiconductor wafer at the stage of processing shown in FIG. 6A.

In FIG. 6B, the insulator layer 107 has been formed on the semiconductor layer 105, in accordance with some embodiments. The insulator layer 107 is formed by performing an ion implantation process. The ion implantation process includes depositing ions 150 into the semiconductor layer 105 of a selected depth as described in relation to FIG. 1A. Alternatively, the diffusion process can be utilized to form the insulator layer 107, as described in relation to FIG. 1A.

In FIG. 6B, the semiconductor layer 109 has been formed on the insulator layer 107, in accordance with some embodiments. The semiconductor layer 109 can be formed by an epitaxial growth process as described in relation to FIG. 1A.

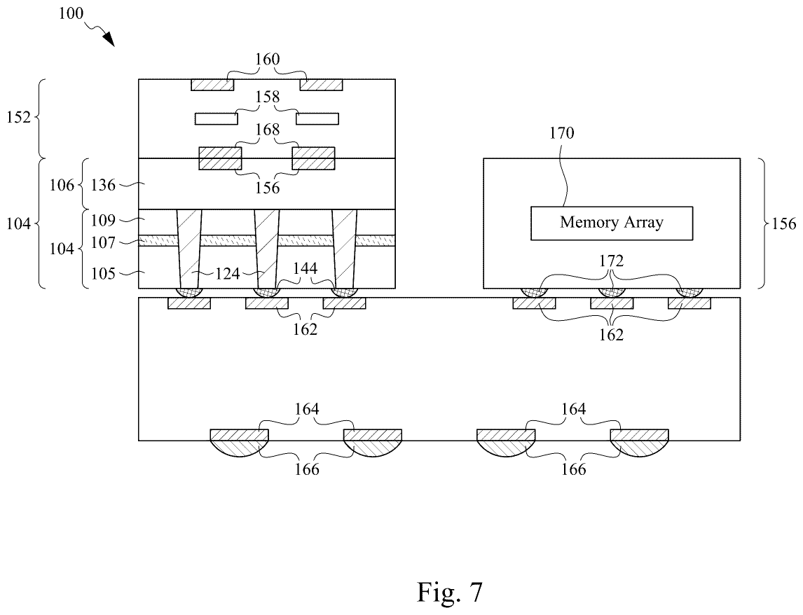

FIG. 7 is a cross-sectional view of an integrated circuit package 100, in accordance with some embodiments. The integrated circuit package 100 includes a substrate 154, the interposer die 102 stacked on the substrate 154, an integrated circuit die 152 stacked on the interposer die 102, and an integrated circuit die 156 stacked on the substrate 154, in accordance with some embodiments. The interposer die 102 does not show all of the structures described in relation to FIGS. 1A-3. The interposer die 102 includes the structures described in relation to FIGS. 1A-3.

The integrated circuit die 152 includes active device regions 158. The integrated circuit die 152 includes top contacts 160 and bottom contact 161. The integrated circuit die 152 can correspond to a processor, a microcontroller, a logic circuit, or other types of circuits. The integrated circuit die 152 may correspond to a system on die (SoC) or other type of integrated circuit die.

The active device regions 158 include a plurality of transistors formed in conjunction with a semiconductor substrate or one or more semiconductor layers of the active device region 158. The transistors can include gate all around transistors each having a plurality of stacked channels with a gate metal wrapped around each of the stacked channels. The transistors can include FinFET transistors. The transistors can include other types of transistors. The transistors can include source/drain regions, gate electrodes, source/drain contacts, and other components. The transistors can be arranged in complex circuit architectures resulting in processing circuits, logic circuits, or other types of circuits capable of complex operations.

Though not shown in FIG. 7, in some embodiments the integrated circuit die 152 includes a front side dielectric stack. The front side dielectric stack can include a plurality of dielectric layers with metal lines and conductive vias formed therein and coupling the active regions 158 to the top contacts 160. In some embodiments, integrated circuit die 152 can include a back side dielectric stack. The back side dielectric stack can include a plurality of dielectric layers with metal lines and conductive vias formed therein and coupling the active regions 158 to the bottom contacts 161.

In some embodiments, substrate 154 is a package substrate such as a PCB substrate, an organic substrate, or other types of substrates. The substrate 154 includes a plurality of upper metal structures 162. The upper metal structures facilitate electrical connection to the bottom contacts 144 of interposer die 104 and to the bottom contacts 172 of the integrated circuit die 156. In particular, each bottom metal structure 144 of the interposer die 104 is coupled to a corresponding top metal structure 162 of the substrate 154.

In some embodiments, the substrate 154 includes bottom metal structures 164 on a bottom surface of the substrate 154. Though not shown in FIG. 1A, the substrate 154 can include package traces or other internal interconnect structures that provide electrical connection between top metal structures 155 and the bottom metal structures 164.

In some embodiments, the integrated circuit die 158 includes a memory array 170. The memory array 170 can correspond to an array of dynamic random-access memory (DRAM) cells, static random-access memory (SRAM) cells, flash memory cells, or other types of memory cells. In an exemplary embodiment, the memory array 170 includes a DRAM array. The integrated circuit die 158 can include a plurality of individual stacked memory dies each including a portion of the memory array 170. The integrated circuit die 158 can include bottom metal structures each coupled to an external interconnection structure 172. The external interconnection structures 172 are each coupled to a top metal structure 162 of the substrate 154.

Though not shown in FIG. 7, after assembly of the components of the integrated circuit package 100, encapsulation can be performed. In other words, the integrated circuit package 100 can include an encapsulation on the substrate 102 surrounding the interposer die 104, the integrated circuit die 152, and the integrated circuit die 158. The encapsulation can be in direct contact with the exposed surfaces of the various structures. The encapsulation can include one or more of a molding compound, a dielectric housing, or other structures to protect the integrated circuit die 102, the interposer die 104, and the integrated circuit die 158.

After assembly of the integrated circuit package 100, the integrated circuit package 100 can be mounted on a circuit board of an electronic device. The surface level interconnection structures on the bottom of the substrate 154 can be coupled to corresponding structures on the circuit board. Signals can be passed from the circuit board through the substrate 154, via the interposer die 102, to the integrated circuit die 152. Signals can be passed to the integrated circuit die 158 via the substrate 154. Similarly, signals can be passed from the integrated circuit die 152 and the integrated circuit die 158 through the substrate 154 to the circuit board.

Though not shown in FIG. 7, in some embodiments, a plurality of integrated circuit dies 152 can be positioned on the interposer die 104.

Principles of the present disclosure can extend to various types of integrated circuit packages. Accordingly, the integrated circuit package 100 can include an interposer-based package, a local silicon interconnect (LSI) based package, an integrated fan out (InFO) based package, a die on the wafer on substrate based package, multiple dies side-by-side on an interposer, a system on integrated chip (SoIC) based package, a wafer on wafer (WoW) based package, or other types of packages.

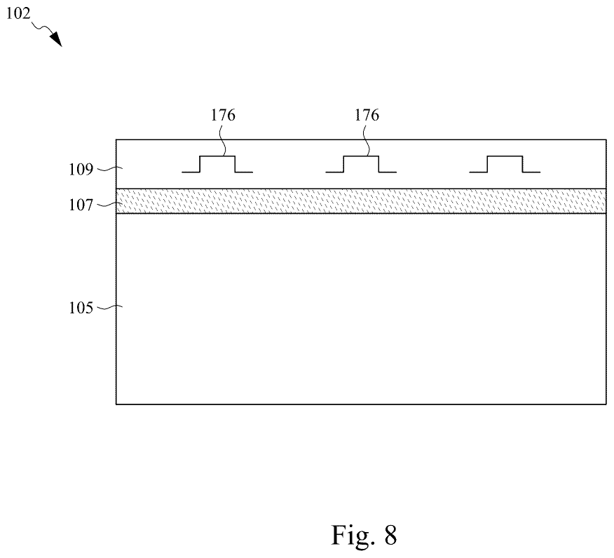

FIG. 8 is a cross-sectional view of an interposer die 102, in accordance with some embodiments. The interposer die includes the semiconductor layer 105, the insulator layer 107, and the semiconductor layer 109 as described in relation to previous figures. The interposer die 102 also includes a plurality of transistors 176 in the semiconductor layer 109. Accordingly, the interposer die 102 can also correspond to a logic die. Though not shown in FIG. 8, through-semiconductor vias 124 are also present in the interposer die 102 of FIG. 8.

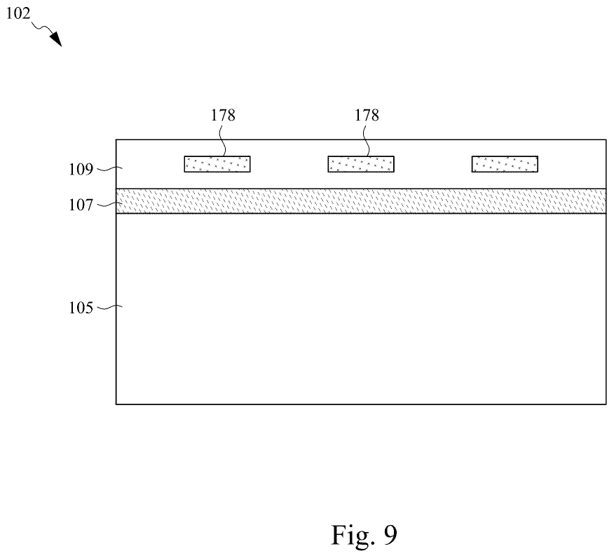

FIG. 9 is a cross-sectional view of an interposer die 102, in accordance with some embodiments. The interposer die 102 includes the semiconductor layer 105, the insulator layer 107, and the semiconductor layer 109 as described in relation to previous figures. The interposer die 102 also includes a plurality of photonic structures 178 in the semiconductor layer 109. The photonic structures 178 include patterned semiconductor structures that pass light signals as a waveguide. Accordingly, the interposer die 102 can also correspond to a photonic or optical die. Though not shown in FIG. 9, through-semiconductor vias 124 are also present in the interposer die 102 of FIG. 9.

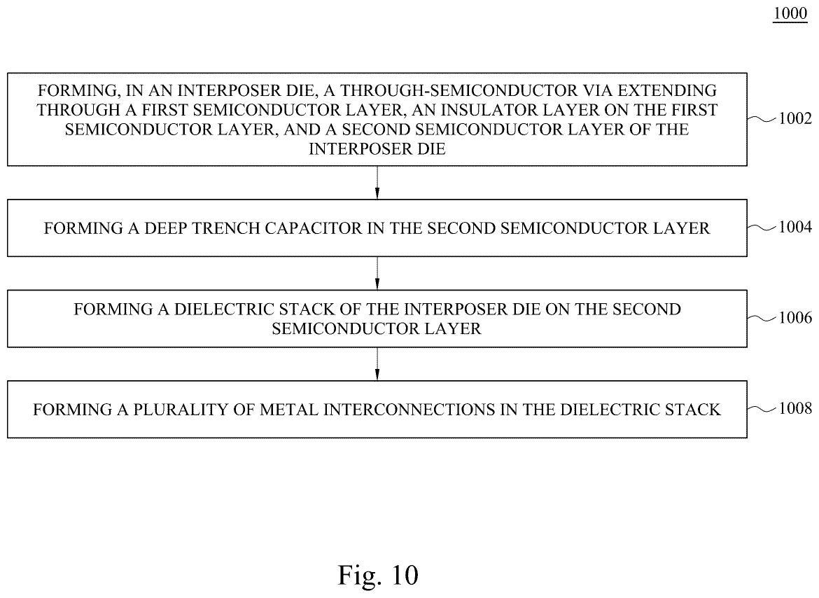

FIG. 10 is a flow diagram of a method 1000, in accordance with some embodiments. The method 1000 can utilize processes, components, and systems described in relation to the foregoing figures. At 1002, the method 1000 includes forming, in an interposer die, a through-semiconductor via extending through a first semiconductor layer, an insulator layer on the first semiconductor layer, and a second semiconductor layer of the interposer die. One example of an interposer die is the interposer die 102 of FIG. 1G. One example of a through-semiconductor via is the through-semiconductor via 124a of FIG. 1G. One example of a first semiconductor layer is the semiconductor layer 105 of FIG. 1G. One example of an insulator layer is the insulator layer 107 of FIG. 1G. One example of a second semiconductor layer is the semiconductor layer 109 of FIG. 1G. At 1004, the method 1000 includes forming a deep trench capacitor in the second semiconductor layer. Of a deep trench capacitor is that the trench capacitor 116 of FIG. 1G. At 1006, the method 1000 includes forming a dielectric stack of the interposer die on the second semiconductor layer. One example of a dielectric stack is the dielectric stack 106 of FIG. 1G. At 1008, the method 1000 forming a plurality of metal interconnections in the dielectric stack. One example of metal interconnections are the metal interconnections 138 of FIG. 1G.

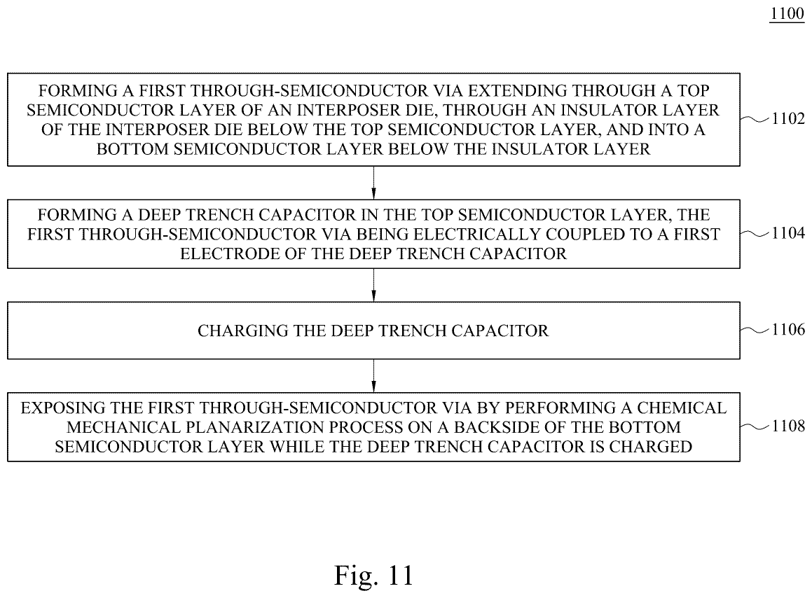

FIG. 11 is a flow diagram of a method 1100, in accordance with some embodiments. The method 1100 can utilize processes, components, and systems described in relation to the foregoing figures. At 1102, the method 1100 includes forming a first through-semiconductor via extending through a top semiconductor layer of an interposer die, through an insulator layer of the interposer die below the top semiconductor layer, and into a bottom semiconductor layer below the insulator layer. One example of an interposer die is the interposer die 102 of FIG. 1A. One example of a through-semiconductor via is the through-semiconductor via 124a of FIG. 1A. One example of a top semiconductor layer is the semiconductor layer 109 of FIG. 1A. One example of an insulator layer is the insulator layer 107 of FIG. 1A. One example of a bottom semiconductor layer is the semiconductor layer 105 of FIG. 1A. At 1104, the method includes forming a deep trench capacitor in the top semiconductor layer, the first through-semiconductor via being electrically coupled to a first electrode of the deep trench capacitor. One example of a deep trench capacitor is the deep trench capacitor one sixteen of FIG. 1A. One example of a first electrode is the electrode 118 of FIG. 1A. At 1106, the method 1100 includes charging the deep trench capacitor. At 1108, the method 1100 includes exposing the first through-semiconductor via by performing a chemical mechanical planarization process on a backside of the bottom semiconductor layer while the deep trench capacitor is charged.

Embodiments of the present disclosure provide an interposer die including an embedded deep trench capacitor (DTC) and having backside contacts with improved electrical characteristics. Embodiments of the present disclosure utilize an insulator layer between two semiconductor layers in the interposer die. The interposer die also includes one or more through-semiconductor vias extending through the second semiconductor layer, the insulator layer, and the first semiconductor layer to a backside of the first semiconductor layer. Backside contacts are coupled to the through-semiconductor vias. The presence of the insulator layer will help reduce the presence of unwanted copper residue at the backside of the first semiconductor layer during charging of the deep trench capacitor. The result is that backside contacts can be formed with a better semiconductor surface profile. This results in reduced leakage. This also results in fewer scrapped wafers. When the interposer is die is embedded in an integrated circuit package, the overall integrated circuit package will have much higher performance. Embodiments of the present disclosure also result in fewer scrapped integrated circuit packages.

In some embodiments, a method includes forming, in an interposer die, a through-semiconductor via extending through a first semiconductor layer, an insulator layer on the first semiconductor layer, and a second semiconductor layer of the interposer die. The method includes forming a deep trench capacitor in the second semiconductor layer, forming a dielectric stack of the interposer die on the second semiconductor layer, and forming a plurality of metal interconnections in the dielectric stack.

In some embodiments, a method includes forming a first through-semiconductor via extending through a top semiconductor layer of an interposer die, through an insulator layer of the interposer die below the top semiconductor layer, and into a bottom semiconductor layer below the insulator layer. The method includes forming a deep trench capacitor in the top semiconductor layer, the first through-semiconductor via being electrically coupled to a first electrode of the deep trench capacitor and charging the deep trench capacitor. The method includes exposing the first through-semiconductor via by performing a chemical mechanical planarization process on a backside of the bottom semiconductor layer while the deep trench capacitor is charged.

In some embodiments, a device includes a first integrated circuit die. The first integrated circuit die includes a first semiconductor layer, an insulator layer on the first semiconductor layer, and a second semiconductor layer on the insulator layer and separated from the first semiconductor layer by the insulator layer. The interposer die includes a first through-semiconductor via extending from a top surface of the second semiconductor layer, through the insulator layer, to a bottom surface of the first semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming, in an interposer a through-semiconductor via extending through a first semiconductor layer, an insulator layer on the first semiconductor layer, and a second semiconductor layer of the interposer;
forming a deep trench capacitor in the second semiconductor layer;
forming a dielectric stack of the interposer on the second semiconductor layer; and
forming a plurality of metal interconnections in the dielectric stack.

2. The method of claim 1, wherein the deep trench capacitor extends through the second semiconductor layer and the insulator layer and into the first semiconductor layer.

3. The method of claim 1, wherein the insulator layer is below a bottom of the deep trench capacitor.

4. The method of claim 1, comprising:
forming the insulator layer by depositing a dielectric material on the first semiconductor layer prior to forming the through-semiconductor via; and
forming the second semiconductor layer by performing an epitaxial growth on the insulator layer prior to forming the through-semiconductor via.

5. The method of claim 1, comprising:
forming the insulator layer by performing an ion implantation process on the first semiconductor layer prior to forming the through-semiconductor via; and
forming the second semiconductor layer by performing an epitaxial growth process on the insulator layer.

6. The method of claim 1, comprising:
forming the insulator layer by performing a diffusion process on the first semiconductor layer prior to forming the through-semiconductor via; and
forming the second semiconductor layer by performing an epitaxial growth process on the insulator layer.

7. The method of claim 1, comprising forming a solder bump on a bottom of the through-semiconductor via.

8. The method of claim 1, comprising:
mounting the interposer to a substrate; and
mounting a first integrated circuit die on the interposer, the first integrated circuit die including a plurality of transistors.

9. The method of claim 8, comprising mounting a second integrated circuit die on the substrate laterally separated from the interposer.

10. The method of claim 8, comprising encapsulating the first integrated circuit die and the interposer in a package.

11. A method, comprising:
forming a first through-semiconductor via extending through a top semiconductor layer of an interposer, through an insulator layer of the interposer below the top semiconductor layer, and into a bottom semiconductor layer below the insulator layer;
forming a deep trench capacitor in the top semiconductor layer, the first through-semiconductor via being electrically coupled to a first electrode of the deep trench capacitor;
charging the deep trench capacitor; and
exposing the first through-semiconductor via by performing a chemical mechanical planarization process on a backside of the bottom semiconductor layer while the deep trench capacitor is charged.

12. The method of claim 11, comprising:
forming a second through-semiconductor via through the top semiconductor layer, through the insulator layer, and into the bottom semiconductor layer, wherein a second electrode of the deep trench capacitor is coupled to the second through-semiconductor layer; and
exposing the second through-semiconductor via with the chemical mechanical planarization process.

13. The method of claim 12, wherein the first through-semiconductor via is configured to supply ground voltage, wherein the second through-semiconductor via is configured to supply a high supply voltage.

14. A device, comprising:
a first integrated circuit die including:
a first semiconductor layer;
an insulator layer on the first semiconductor layer;
a second semiconductor layer on the insulator layer and separated from the first semiconductor layer by the insulator layer; and
a first through-semiconductor via extending from a top surface of the second semiconductor layer, through the insulator layer, to a bottom surface of the first semiconductor layer.

15. The device of claim 14, wherein the first integrated circuit die includes:
a second through-semiconductor via extending from the top surface of the second semiconductor layer, through the insulator layer, to the bottom surface of the semiconductor layer; and
a deep trench capacitor including:
a first electrode extending into the second semiconductor layer from the top surface of the second semiconductor layer and electrically coupled to the first through-semiconductor via; and
a second electrode extending into the second semiconductor layer from the top surface of the second semiconductor layer and electrically coupled to the second through-semiconductor via.

16. The device of claim 15, wherein the first electrode and the second electrode extend through the insulator layer into the first semiconductor layer.

17. The device of claim 14, wherein the insulator layer is below a bottom of first electrode and a bottom of the second electrode.

18. The device of claim 14, wherein the first integrated circuit die includes:
a dielectric layer on the second semiconductor layer;
a conductive via extending through the dielectric layer and contacting the top surface of the second semiconductor layer directly above the insulator layer and configured to supply ground voltage to the top surface of the second semiconductor layer; and
an insulator structure including:
the insulator layer; and
an insulator column of dielectric material extending from top surface of the second semiconductor layer to a top surface of the insulator layer.

19. The device of claim 14, comprising:
a substrate, wherein the first integrated circuit die is mounted on the substrate and the substrate is electrically connected to the first through-semiconductor via; and
a second integrated circuit die mounted on the first integrated circuit die and electrically coupled to the substrate by the first through-semiconductor via.

20. The device of claim 14, comprising a plurality of transistors in the second semiconductor layer.
